(19) United States
(12) Patent Application Publication
(10) Pub. No.: US 2024/0146030 A1
(43) Pub. Date: May 2, 2024

(54) SEMICONDUCTOR DEVICE

(71) Applicant: EPISTAR CORPORATION, Hsinchu City (TW)

(72) Inventors: Shih-Chun LING, Hsinchu City (TW); Wan-Jung Lee, Hsinchu City (TW)

(21) Appl. No.: 18/494,018

(22) Filed: Oct. 25, 2023

(30) Foreign Application Priority Data
Oct. 26, 2022 (TW) 111140701

(51) Int. Cl. H01S 5/22; B23K 26/38; H01S 5/10

(52) U.S. Cl. CPC H01S 5/22; B23K 26/38; H01S 5/1039; H01S 5/0201

(57) ABSTRACT

A semiconductor device is provided. The semiconductor device includes a substrate and a stack structure. The substrate includes a first upper region, a second upper region, a third upper region and a fourth upper region. The stack structure locates on the fourth upper region of the substrate without overlapping the first upper region, the second upper region and the third upper region. The stack structure includes a first end face, a top surface, a first semiconductor layer, an active region, and a second semiconductor layer. The second semiconductor layer includes a ridge structure. The first upper region is closer to the light emitting end face than the second upper region is. The semiconductor device has a first depth between the top surface and the first upper region, and a second depth between the top surface and the second upper region smaller than the first depth.

### CROSS REFERENCE TO RELATED APPLICATIONS

This application claims priority of Taiwan Patent Application No. 111140701, filed on Oct. 26, 2022, and the entirety of which is incorporated by reference herein.

### BACKGROUND

### Technical Field

The present application relates to a semiconductor device, and, in particular, to a semiconductor laser device.

### Description of the Background Art

Recently, the demand of the semiconductor device is getting stronger and the application range is also getting wider. During the process of dividing the wafer and forming the single laser device, the splatters caused by the laser scribing process usually pollute the laser device.

### SUMMARY

Some embodiments of the present disclosure provide a semiconductor device, especially the semiconductor device that is able to decrease the probability that the splatters pollute a light-emitting surface of the semiconductor device during the laser cutting process.

Some embodiments of the present disclosure provide a semiconductor device. The semiconductor device includes a substrate and a stack structure. The substrate includes a first upper region, a second upper region, a third upper region and a fourth upper region. The stack structure locates on the fourth upper region of the substrate without overlapping the first upper region, the second upper region and the third upper region. The stack structure includes a first end face, a top surface, a first semiconductor layer, an active region, and a second semiconductor layer. The second semiconductor layer includes a ridge structure. The first upper region is closer to the first end face than the second upper region is. The semiconductor device has a first depth between the top surface and the first upper region, and a second depth between the top surface and the second upper region smaller than the first depth.

### BRIEF DESCRIPTION OF THE DRAWINGS

The embodiment of the application can be more fully understood by reading the subsequent detailed description and examples with references made to the accompanying drawings. It is noted that, in accordance with the standard practice in the industry, various features are not drawn to scale and are merely used for illustration. In fact, the dimensions of the various components may be arbitrarily increased or reduced to clearly represent the features of the embodiments of the present disclosure. In the accompanying drawings:

FIG. 1 shows a top view of semiconductor device in accordance with one embodiment of the present disclosure.

FIG. 2 shows a cross-sectional view along A1-A1′ line of the semiconductor device shown in FIG. 1 in accordance with one embodiment of the present disclosure.

FIG. 3 shows a cross-sectional view along A2-A2′ line of the semiconductor device shown in FIG. 1 in accordance with one embodiment of the present disclosure.

FIG. 4 shows a cross-sectional view along A3-A3′ line of the semiconductor device shown in FIG. 1 in accordance with one embodiment of the present disclosure.

FIG. 5 shows a cross-sectional view along B-B′ line of the semiconductor device shown in FIG. 1 in accordance with one embodiment of the present disclosure.

FIG. 6A shows a representative picture of the first trench, the second trench and the third trench exposing the upper surface of the substrate in accordance with one embodiment of the present disclosure.

FIG. 6B shows a representative picture of the first trench, the second trench and the third trench exposing the bottom surface of the substrate in accordance with one embodiment of the present disclosure.

FIG. 7 shows a top view of semiconductor bar in accordance with one embodiment of the present disclosure.

FIG. 8A shows a cross-sectional view along C-C′ line of the semiconductor bar shown in FIG. 7 in accordance with one embodiment of the present disclosure.

FIG. 8B shows a cross-sectional view along D-D′ line of the semiconductor bar shown in FIG. 7 in accordance with one embodiment of the present disclosure.

FIG. 8C shows a cross-sectional view along E-E′ line of the semiconductor bar shown in FIG. 7 in accordance with one embodiment of the present disclosure.

FIG. 8D shows a cross-sectional view along E-E′ line of the semiconductor bar shown in FIG. 7 in accordance with another embodiment of the present disclosure.

FIGS. 9A-9J show a process flow of manufacturing the semiconductor device in accordance with another embodiment of the present disclosure.

FIG. 10 shows a cross-sectional view of the semiconductor system in accordance with another embodiment of the present disclosure.

### DETAILED DESCRIPTION OF THE PREFERRED EMBODIMENTS

The embodiments provide a semiconductor device, particularly a semiconductor laser device, which is able to eliminate the pollution on the emitting end face or reflective end face of the chip caused by laser scribing process. Therefore, the problem of yield loss streamed from the splatters polluting the end faces and the decrease of light emitting performance can be solved.

The following disclosure provides various embodiments. Specific examples of components and arrangements are described below to simplify the present disclosure. These are, of course, merely examples and are not intended to limit the present disclosure. For example, the formation of a first component over or on a second component in the following description may include embodiments in which the first and second components are formed in direct contact, and may also include embodiments in which additional components may be located between the first and second components, such that the first and second components may not be in direct contact. In addition, the present disclosure may repeat reference numerals and/or letters in the various examples. This repetition is for the purpose of simplicity and clarity and does not in itself dictate a relationship between the various embodiments and/or configurations. Besides, various components may be arbitrarily drawn in various scale for the purpose of simplicity and clarity.

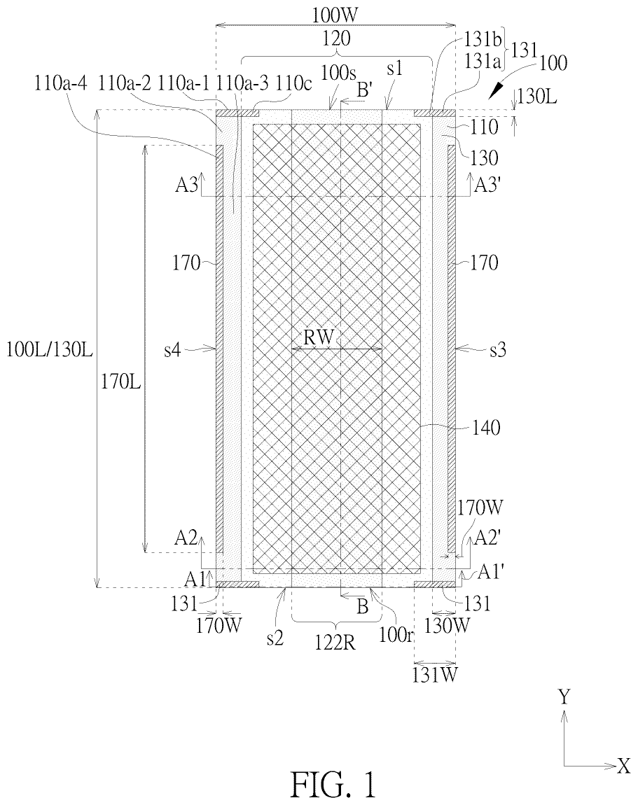

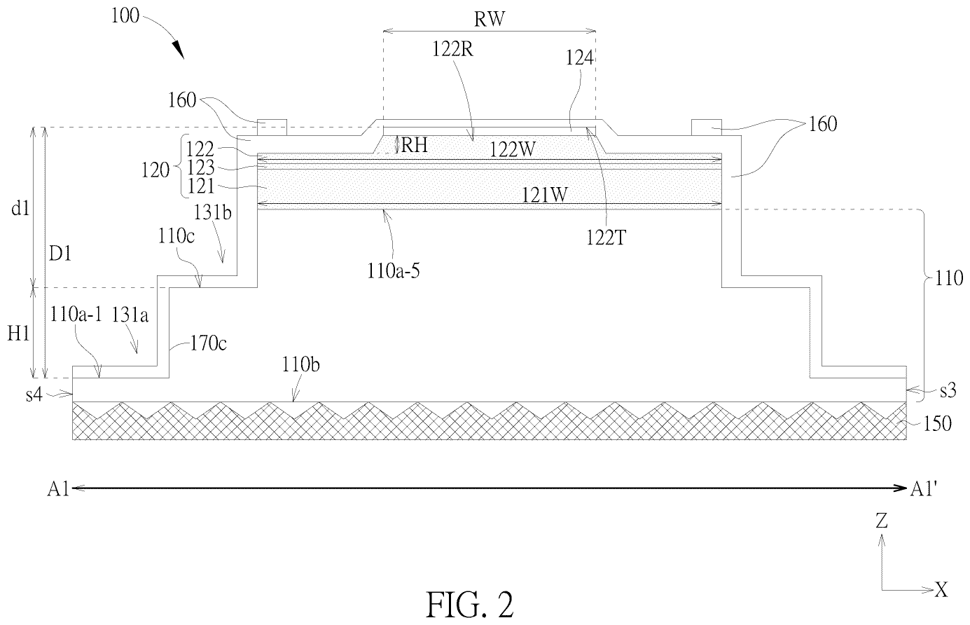

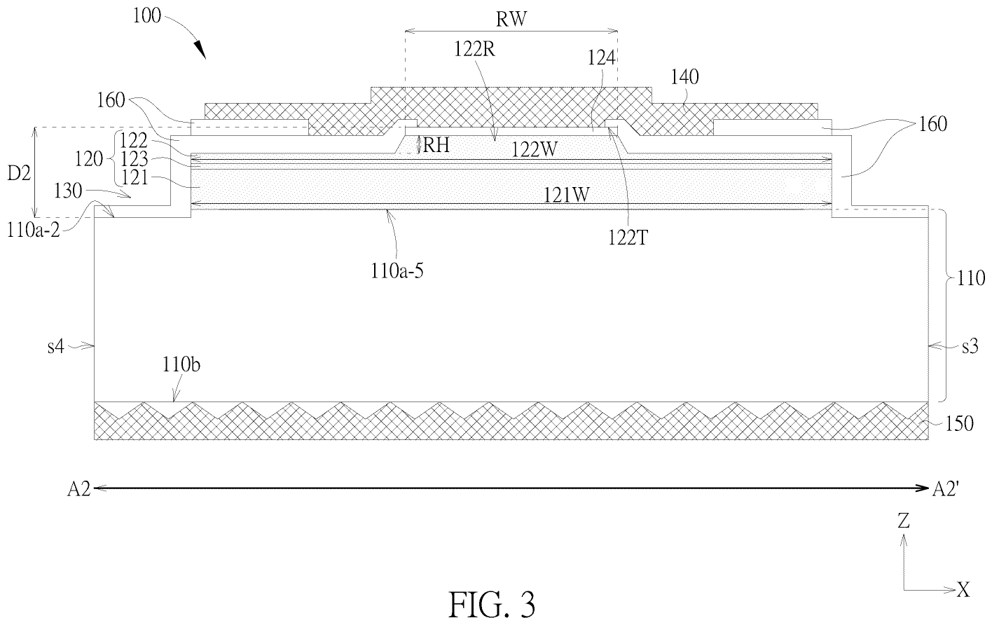

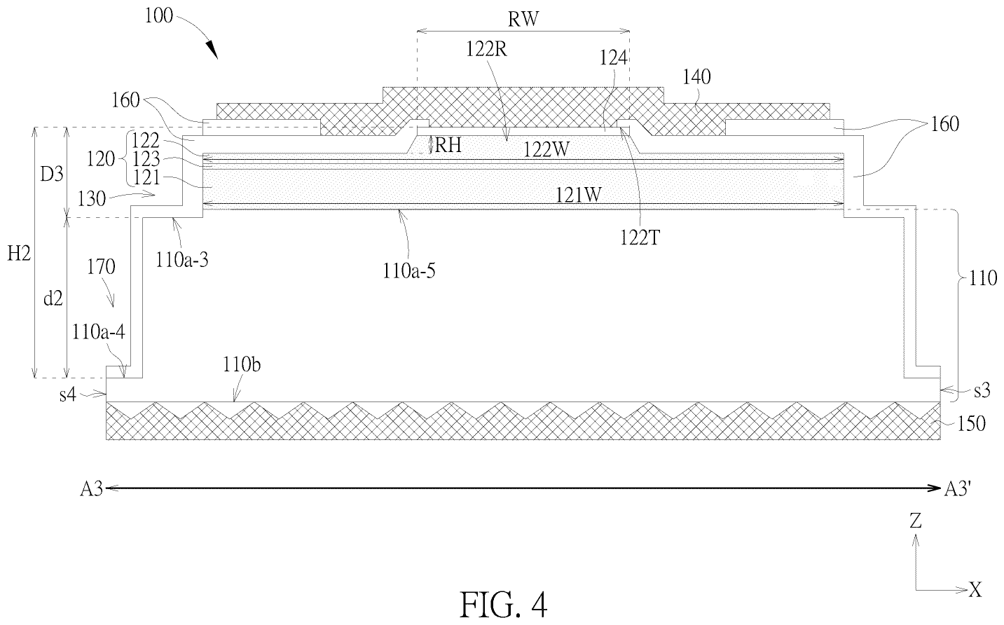

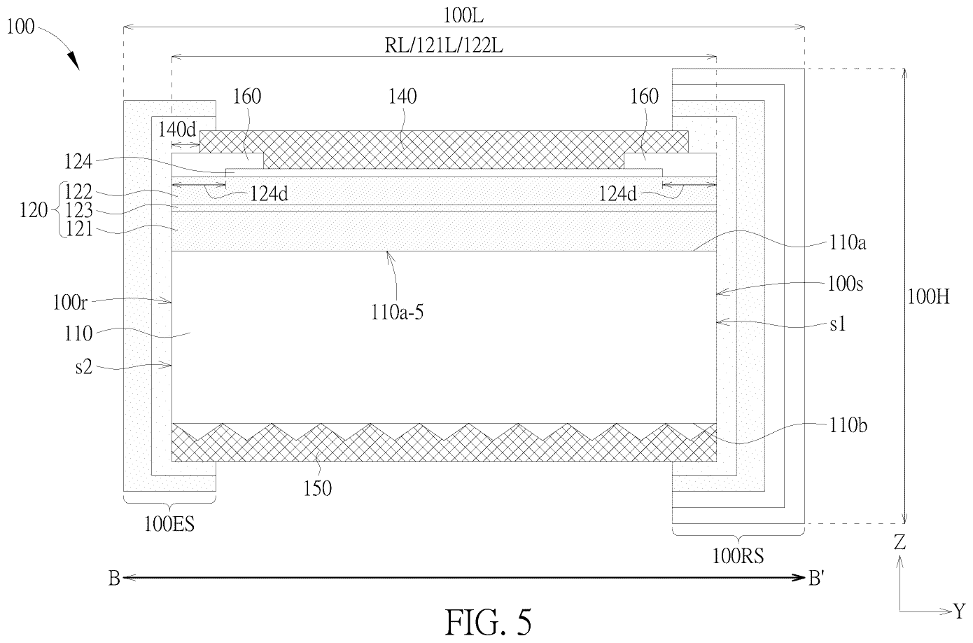

FIG. 1 shows a top view of a semiconductor device 100 in accordance with an embodiment of the present disclosure. The semiconductor device 100 is on a plane formed of X direction and Y direction shown in FIG. 1. FIG. 2 shows a cross-sectional view along A1-A1′ line of the semiconductor device shown in FIG. 1 in accordance with one embodiment of the present disclosure. FIG. 3 shows a cross-sectional view along A2-A2′ line of the semiconductor device shown in FIG. 1 in accordance with one embodiment of the present disclosure. FIG. 4 shows a cross-sectional view along A3-A3′ line of the semiconductor device shown in FIG. 1 in accordance with one embodiment of the present disclosure. FIG. 5 shows a cross-sectional view along B-B′ line of the semiconductor device shown in FIG. 1 in accordance with one embodiment of the present disclosure. The semiconductor device 100 is on a plane formed of X direction and Z direction shown in FIGS. 2, 3, 4. The semiconductor device 100 is on a plane formed of Y direction and Z direction shown in FIG. 5. The X direction, Y direction and Z direction represent different directions and are perpendicular to each other, but the present disclosure is not limited by above description.

As shown in FIGS. 1-4, the semiconductor device 100 includes a substrate 110 and a stack structure 120 having a ridge structure 122R on the substrate 110. The substrate 110 includes an upper surface 110a and a bottom surface 110b opposite to the upper surface 110a. The upper surface 110a includes a first upper region 110a-1, a second upper region 110a-2, a third upper region 110a-4 a fourth upper region 110a-5, the fifth upper region 110c and a sixth upper region 110a-3. The stack structure 120 locates on the fourth upper region 110a-5 and does not overlap with the first upper region 110a-1, the second upper region 110a-2, the third upper region 110a-4, the fifth upper region 110c, and a sixth upper region 110a-3. The first upper region 110a-1, the second upper region 110a-2 or the third upper region 110a-4 can be flat or rough.

The semiconductor device 100 further includes a first trench 131, a second trench 130 and a third trench 170. The first trench 131 connects to the second trench 130. The third trench 170 is parallel to the second trench 130. The first trench 131 exposes the first upper region 110a-1, the second trench 130 exposes the second upper region 110a-2, and the third trench 170 exposes the third upper region 110a-4. The first trench 131 includes a first trench width 131W and a first trench length 131L. The second trench 130 includes a second trench width 130W narrower than the first trench width 131W and a second trench length 130L larger than the first trench length 131L. The third trench 170 includes a third trench width 170W narrower than the second trench width 130W and a third trench length 170L smaller than the second trench length 130L. The second trench 130 is closer to the ridge structure 122R than the third trench 170 is.

The stack structure 120 includes a first semiconductor layer 121, a second semiconductor layer 122, and an active region 123 between the first semiconductor layer 121 and the second semiconductor layer 122. The stack structure 120 includes a light emitting end face 100r, a reflective end face 100s and a top surface 122T. The first upper region 110a-1 is closer to the light emitting end face 100r than the second upper region 100a-2 is. The second upper region 110a-2 is closer to the light emitting end face 100r than the third upper region 110a-4 is.

As shown in FIGS. 1-4, the semiconductor device 100 includes a first depth D1 between the top surface 122T and the first upper region 110a-1, and a second depth D2 between the top surface 122T and the second upper region 110a-2. The second depth D2 is smaller than the first depth D1. The semiconductor device 100 further includes a third depth H2 between the top surface 122T and the third upper region 110a-4 larger than the second depth D2. In the embodiment, the third depth H2 is substantially the same as the first depth D1.

The fifth upper region 110c of the substrate 110 is closer to the light emitting end face 100r than the second upper region 110a-2 is. The semiconductor device 100 further includes a fourth depth dl between the top surface 122T and the fifth upper region 110c. The fourth depth dl is larger than the second depth D2. The sixth upper region 110a-3 is closer to the ridge structure 122R than the third upper region 110a-4 is. The semiconductor device 100 includes a fifth depth D3 between the top surface 122T and the sixth upper region 110a-3, and the fifth depth D3 is smaller than third depth H2. In the embodiment, the fifth depth D3 is substantially the same as the second depth D2.

In one embodiment, the first depth D1, the second depth D2 and the fifth depth D3 can be the same. In one embodiment, the first depth D1, the second depth D2 and the fifth depth D3 can be different from one another. For example, the first depth D1 is larger than the second depth D2, and the second depth D2 is substantially the same with or different from the fifth depth D3. The first depth D1 can be 12 μm-35 μm, 18 μm-30 μm, or 20 μm-28 μm. The second depth D2 can be 0.1 μm-10 μm, 2 μm-8 μm, or 3 μm-5 μm. The fifth depth D3 can be 0.1 μm-10 μm, 2 μm-8 μm, or 3 μm-5 μm. In one embodiment, the first depth D1, the second depth D2 and the fifth depth D3 can be determined from the conductive contact layer 124 or the upper electrode 140 to the specific upper region. In other words, the top surface 122T can be the top surface of the stack structure 120, the top surface of the conductive contact layer 124 or the top surface of the upper electrode 140. In one embodiment as shown in FIGS. 2-4, the first depth D1, the second depth D2, and the fifth depth D3 are parallel to Z direction.

In some embodiments, the first trench 131 and the second trench 130 of the semiconductor device 100 are connected or partially overlapped. A gap locates between two first trenches 131 adjacent to the first side surface s1 in order to devoid breaking the light emitting end face. The gap can be 90 μm-170 μm, 100 μm-160 μm or 110 μm-150 μm. In some embodiments, a fourth depth dl between the top surface 122T and the fifth upper region 110c is the same as or smaller than the first depth D1. In some embodiments, the fifth upper region 110c and the first upper region 110a-1 can be on the same horizontal plane. In some embodiments, a first step height H1 forms between the fifth upper region 110c and the first upper region 110a-1, and the two upper regions 110c, 110a-1 locate on different horizontal plane. The first step height H1, the second depth D2, and/or the fifth depth D3 are substantially the same. For example, the first step height H1 can be 0.1 μm-10 μm, 2 μm-8 μm, or 3 μm-5 μm. In one embodiment, the fourth depth dl and the first step height H1 are parallel to Z direction. In one embodiment, the first trench 131 comprises a first part 131a and a second part 131b connecting to the first part 131a. The first part 131a exposes the first upper region 110a-1 and the second part 131b exposes the fifth upper region 110c. The second part 131b of the first trench 131 is closer to the ridge structure 122R than the first part 131a is. The first part 131a of the first trench 131 connects to the second trench 130.

In some embodiments, the third trench 170 and the second trench 130 of the semiconductor device 100 are connected, partially overlapped or fully overlapped as shown in FIG. 1. As shown in FIG. 4, the third trench 170 exposes the substrate 110. More specifically, the third upper region 110a-4 is exposed by the third trench 170. In some embodiments, a second step height d2 is between the sixth upper region 110a-3 and the third upper region 110a-4, or between the third upper region 110a-4 and the second upper region 110a-2 (not shown). The second step height d2 is larger than the second depth D2 and/or the fifth depth D3. In some embodiments, there is a step height between the third upper region 110a-4 and the second upper region 110a-2 and/or the third upper region 110a-4 and the sixth upper region 110a-3, and the third upper region 110a-4 and the second upper region 110a-2 and/or the third upper region 110a-4 and the sixth upper region 110a-3 in different horizontal planes. In some embodiments, the third upper region 110a-4 can be parallel to the sixth upper region 110a-3, or the third upper region 110a-4 can include an inclined surface and without parallel to the sixth upper region 110a-3. In one embodiment, the second step height d2 is parallel to Z direction. In the embodiment, the second trench 130 connects to the third trench 170, and the first trench 131 separates from the third trench 170.

The semiconductor device 100 further includes an upper electrode 140, a bottom electrode 150, and a protective layer 160 between the upper electrode 140 and the stack structure 120 as shown in FIGS. 3-4. The semiconductor device 100 has a device length 100L, a device width 100W as shown in FIG. 1, and a device height 100H as shown in FIG. 5. The device length 100L can be 840 μm-1560 μm, 960 μm-1440 μm or 1080 μm-1212 μm. The device width 100W can be 140 μm-260 μm, 160 μm-240 μm or 180 μm-220 μm. The device height 100H can be 70 μm-120 μm.

The second trench width 130W of the second trench 130 can be 2 μm-20 μm, 5 μm-15 μm or 7 μm-13 μm. The second trench length 130L can be 840 μm-1560 μm, 960 μm-1440 μm or 1080 μm-1212 μm. In some embodiment, the third trench width 170W can be 1 μm-9 μm, 3 μm-7 μm or 4 μm-6 μm.

The substrate 110 further includes a first side surface s1, a second side surface s2, a third side surface s3 and a fourth side surface s4. The first side surface s1 is opposite to the second side surface s2, and the third side surface s3 is opposite to the fourth side surface s4. The first side surface s1 can be parallel to the second side surface s2. The third side surface s3 is not parallel to the first side surface s1, and the fourth side surface s4 is not parallel to the second side surface s2. The upper surface 110a connects to the bottom surface 110b through the first side surface s1, the second side surface s2, the third side surface s3 and/or the fourth side surface s4. In the embodiment, the semiconductor device 100 is a rectangle in the top view of X-Y plane. For example, the first side surface s1 and the second side surface s2 are shorter than the third side surface s3 and the fourth side surface s4, the first side surface s1 is connecting and perpendicular to the third side surface s3 and the fourth side surface s4, and the second side surface s2 is connecting and perpendicular to the third side surface s3 and the fourth side surface s4. In other words, the substrate 110 includes four corners C, two outer short-side surfaces s1, s2, and two outer long-side surfaces s3, s4. Each of the corners C locates between one outer short-side surface and one outer long-side surface. In the embodiment, the substrate 110 includes four first trenches 131 respectively locating at the four corners, two second trenches 130 respectively disposing near the two outer long-side surfaces s3, s4, and two third trenches 170 respectively overlapping with the two second trenches 130.

In some embodiment, the substrate 110 can be silicon substrate, nitride-based semiconductor substrate, SiC substrate or GaAs substrate. In one embodiment, the substrate 110 can be further processed by a thinning process or patterned process, and so on. For example, the bottom surface 110b of the substrate 110 can be a rough surface after a patterned process. In one embodiment, the substrate 110 includes III-Vsemiconductor material. The material has chemical formula: InₓAl_{y}Ga_{1-x-y}N (0≤x, 0≤y, x+y≤1). For example, the material of the substrate 110 can be GaN or other suitable material. The upper surface 110a of the substrate 110 may include (0001) lattice plane, (000-1) lattice plane, (0-10) lattice plane, (11-20) lattice plane, (10-14) lattice plane, (10-15) lattice plane or (11-24) lattice plane. In the embodiment, (0001) lattice plane is chosen to be the epitaxial growing surface of the stack structure 120. The substrate 110 includes a thickness between 70 μm and 120 μm. In some embodiments, the substrate 110 can be n-type GaN and able to conduct current.

In some embodiment, the second trench 130 of the semiconductor device 100 exposes the upper surface 110a of the substrate 110. The first upper region 110a-1, the second upper region 110a-2, and the sixth upper region 110a-3 can be the same level with, or different levels to the other upper regions. In one embodiment, the first upper region 110a-1, the second upper region 110a-2, and the sixth upper region 110a-3 are on different levels. For example, the first upper region 110a-1 is closer to the bottom surface 110b than the second upper region 110a-2 and the sixth upper region 110a-3 are. The second upper region 110a-2 and the sixth upper region 110a-3 can be on the same or different level(s).

The stack structure 120 locates on the fourth upper region 110a-5 and sequentially includes a first semiconductor layer 121, an active region 123 and a second semiconductor layer 122 along Z-direction (stacking direction). The first semiconductor layer 121 includes n-type semiconductor material, such as n-type nitride semiconductor material. The second semiconductor layer 122 includes p-type semiconductor material, such as p-type nitride semiconductor material. In one embodiment, the first semiconductor layer 121 includes n-type nitride semiconductor material with a first dopant and the second semiconductor layer 122 includes p-type nitride semiconductor material with a second dopant. The n-type nitride semiconductor material with the first dopant can be nitride-based semiconductor layer doped with Si, C, Ge, Sn, Pb or O. The n-type nitride semiconductor material with the second dopant can be nitride-based semiconductor layer doped with Mg, Li, Na, K, Be, Zn or Ca. The chemical formula of the nitride-based semiconductor layer is InₓAl_{y}Ga_{1-x-y}N (0≤x, 0≤y, x+y≤1). In one embodiment, the stack structure 120 includes a contact layer (not shown) on the second semiconductor layer 122. The contact layer can be a p-type nitride semiconductor layer with the second dopant. A doping concentration of the second dopant in the contact layer can be higher than that in the second semiconductor layer 122. In one embodiment, the doping concentration of the second dopant in the contact layer is higher than 1×10²⁰ cm⁻³, and the doping concentration of the second dopant in the second semiconductor layer 122 is between 5×10¹⁷ cm⁻³ and 5×10¹⁹ cm⁻³. The active region 123 can be doped or undoped. A doping concentration of the first dopant in the first semiconductor layer 121 is between 1×10¹⁸ cm⁻³ and 2×10¹⁹ cm⁻³. The active region 123 can be III-V binary compound semiconductor, such as GaAs, InP, GaP or GaN, III-V multi-element compound semiconductor, such as AlGaAs, InGaN, AlGaN, AlInGaN, GaAsP, AlGaInP or AlInGaAs, or II-VI binary compound semiconductor, such as CdSe, CdS or ZnSe.

As shown in FIGS. 2-5, the first semiconductor layer 121 has a first length 121L and a first width 121W. The first length 121L of the first semiconductor layer 121 can be between 840 μm and 1560 μm, between 960 μm and 1440 μm, or between 1080 μm and 1212 μm. The first width 121W of the first semiconductor layer 121 can be between 140 μm and 260 μm, between 160 μm and 240 μm, or between 180 μm and 220 μm. The second semiconductor layer 122 has a second length 122L and a second width 122W. The second length 122L of the second semiconductor layer 122 can be between 840 μm and 1560 μm, between 960 μm and 1440 μm, or between 1080 μm and 1212 μm. The second width 122W of the second semiconductor layer 122 can be between 140 μm and 260 μm, between 160 μm and 240 μm, or between 180 μm and 220 μm.

The second semiconductor layer 122 includes the ridge structure 122R protruding from the stacking direction. The ridge structure 122R can serve as a light resonator. In the top view of X-Y plane of the semiconductor device 100, the ridge structure 122R is substantially parallel to Y direction and extends along to a long-side direction of the semiconductor device 100. For example, the ridge structure 122R is parallel to the third side surface s3 and extends from the first side surface s1 to the second side surface s2. The ridge structure 122R is designed to be a rectangle and includes a ridge width RW, a ridge length RL and a ridge height RH. The ridge width RW of the ridge structure 122R can be 35 μm-65 μm, 40 μm-60 μm or 45 μm-55 μm. The ridge length RL of the ridge structure 122R can be 840 μm-1560 μm, 960 μm-1440 μm or 1080 μm-1212 μm. The ridge height RH of the ridge structure 122R can be 315 nm-385 nm, 280 nm-420 nm or 245 nm-455 nm.

The longitudinal mode of the semiconductor device relates to the geometric character of the light resonator. In some embodiments, when the ridge width RW of the ridge structure 122R is larger than 5 μm, the device length 100L is 840 μm-1560 μm, and the device width 100W is 130 μm-260 μm, the output light of the semiconductor device 100 is multiple mode. In some embodiments, when semiconductor device 100 has the ridge width RW smaller than 5 μm, the device length 100L is in a range of 120 μm-660 μm, and the device width 100W is in a range of 100 μm-200 μm, the output light of the semiconductor device 100 is single mode.

In some embodiments, the semiconductor device 100 includes a conductive contact layer 124 on the stack structure 120. The material of the conductive contact layer 124 can include transparent conductive oxide, such as Indium Tin Oxide (ITO), Zinc Oxide (ZnO), Zinc Indium Tin Oxide (ZITO), Zinc Indium Oxide (ZIO), Zinc Tin Oxide (ZTO), Gallium Indium Tin Oxide (GITO), Gallium Indium Oxide (GIO), Gallium Zinc Oxide (GZO), Aluminum doped Zinc Oxide (AZO), Fluorine Tin Oxide (FTO), or transparent metal layer with a thickness smaller than 500 Å composed of metal like Al, Ni or Au.

The ridge structure 122R is composed by an upper part of the second semiconductor layer 122. In FIG. 5, in one embodiment, the conductive contact layer 124 locates on the second semiconductor layer 122 and spaces apart from an edge of the stack structure 122 by a contact distance 124d. The contact distance 124d can be 11.9 μm-22.1 μm, 13.6 μm-20.4 μm or 15.3 μm-18.7 μm. In one embodiment, the ridge structure 122R is formed by removing a part of the second semiconductor layer 122 through lithography and etching process after forming the stack structure 120. The upper part of the remaining second semiconductor layer 122 forms the ridge structure 122R.

The semiconductor device 100 includes a first end face and a second end face opposite to the first end face. As shown in FIG. 5, the first end face can be light emitting end face 100r or a reflective surface 100s. When the first end face is light emitting end face 100r, the second end face is the reflective end face 100s. When the first end face is the reflective end face 100s, the second end face is light emitting end face 100r. The light emitting end face 100r and the second end face 100s respectively locate on two sides of the stack structure 120. For example, the light emitting end face 100r and the second end face 100s locates on the opposite sides of the stack structure 120, and are perpendicular to the upper surface 110 and/or the bottom surface 100b of the substrate 110.

In the disclosure, the light emitting end face 100r and the second end face 100s of the semiconductor device 100 are perpendicular to the extending direction of the ridge length RL of the ridge structure 122R. The light emitting end face 100r and the reflective end face 100s compose a resonant cavity of the light resonator. Therefore, the light generated from the active region 123 goes back and forth between the light emitting end face 100r and the second end face 100s so the resonance phenomenon occurs. The light emitting end face 100r is able to emit light outside and the second end face 100s reflects light back to the resonant cavity. The length direction is parallel to the extending direction of the resonant cavity and the width direction is perpendicular to the extending direction of the resonant cavity.

In the embodiment of the disclosure, in order to let light emitting outside from the light emitting end face 100r, a low reflectivity structure 100ES including dielectric material can be formed on the light emitting end face 100r, and a high reflectivity structure 100RS including dielectric material can be formed on the second end face 100s. The low reflectivity structure 100ES can be single film or multifilm. The high reflectivity structure 100RS can be multifilm, and the material of a part of the film of the high reflectivity structure 100RS can be the same as that of the low reflectivity structure 100ES. The dielectric material can be the oxide, nitride, oxynitride of a metal including Al, Si, Nb, Ti, Zr, Hf, Ta, Zn, Y, Ga or Mg. For example, AlₓO_{y} (1<x, 1<y), SiOₓ (1<x), NbₓO_{y} (1<x, 1<y), TiOₓ (1<x), or ZrOₓ (1<x). The reflectivity of the low reflectivity structure 100ES is lower than that of the higher reflectivity structure 100RS. The low reflectivity structure 100ES has a reflectivity between 85% and 90% and includes a material of metal oxides or metal oxynitride, such as Al₂O₃ or AlNOₓ. The high reflectivity structure 100RS has a reflectivity higher than 90% or higher than 95%, and includes several pairs of SiO₂/Ta₂O₅. The high reflectivity structure 100RS further includes Al₂O₃ and SiO₂ respectively locating on two opposite sides of the several pairs of SiO₂/Ta₂O₅.

As shown in FIGS. 2-4, the upper electrode 140 can be p electrode located on the ridge structure 122R and contacts the conductive contact layer 124 and the protective layer 160. On the top view of XY plane, the upper electrode 140 is a rectangle structure or striped structure extending from the first side surface s1 to the second side surface s2 along the direction parallel to the substrate 110, such as along the third side surface s3 or the fourth side surface s4. The upper electrode 140 can cover a part or the whole of the ridge structure 122R (not shown). The upper electrode 140 covers a part of the ridge structure 122R as shown in FIG. 1. An edge of the upper electrode 140 can be apart from the light emitting end face 100r and/or the second end face 100s with a distance 140d. The distance 140d can be 7 μm-13 μm, 8 μm-12 μm, or 9 μm-11 μm.

In some embodiments, the bottom electrode 150 can be n electrode and locates on the bottom surface 110b of the substrate 110. The material of the upper electrode 140 or the bottom electrode 150 can include Pd, Cr, Ti, A1, Au, Pt, the combination of the above material, other suitable conductive material or the composite material made of multiple conductive materials. In some embodiments, the material of the protective layer 160 can include the oxide, nitride or oxynitride of Si, Z, A1, Ta or other suitable insulating material. The thickness of the protective layer 160 is not limited. The bottom electrode 150 can align to the first side surface s1 and/or the second side surface s2 as shown in FIG. 5. In some embodiments, the bottom electrode 150 is apart from the first side surface s1 and/or the second side surface s2 in a distance, and the distance can be 7 μm-13 μm, 8 μm-12 μm or 9 μm-11 μm.

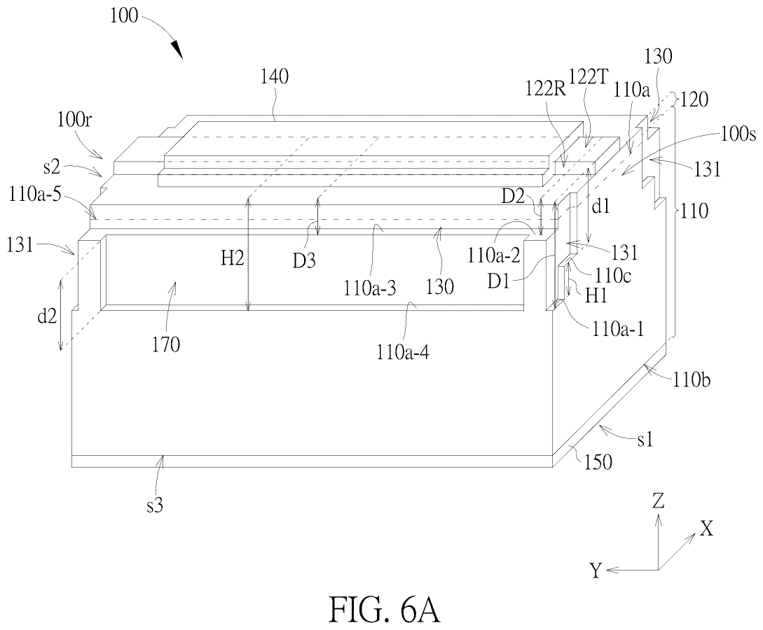

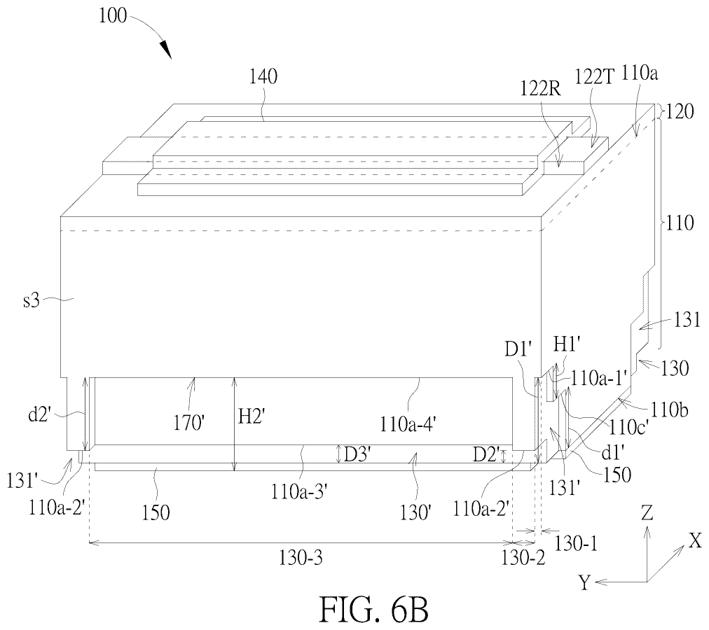

FIG. 6A shows a representative picture of the first trench 131, the second trench 130 and the third trench 170 exposing the upper surface 110a of the substrate 110 in accordance with one embodiment of the present disclosure. Some elements may be omitted in order to clarify the characters in the present disclosure. In some embodiments, multiple first trenches 131 locate on the light emitting end face 110r and the reflective end face 100s, and extends from the top surface 122T toward the bottom surface 110b and exposing the first upper region 110a-1 and the fifth upper region 110c of the substrate 110. In the embodiment, the semiconductor device 100 includes two second trenches 130 respectively locating on two opposite sides of the ridge structure 122R and exposing the substrate 110 as shown in FIG. 1. The semiconductor device 100 further includes four first trenches 131 locating on four corners of the semiconductor device 100 as shown in FIG. 1. The second trenches 130 connect to the first trenches 131 near the first side surface s1 and second side surface s2. The second trenches 130 connect to the first trenches 131 in one-by-one form or one-by-many form. More precisely, in the embodiment, one second trench 130 connects to two first trenches 131. The first trench 131 is closer to the ridge structure 122R than the second trench 130 is. In some embodiments, the first trench(es) 131 and the second trench(es) 130 can be connected, partial or fully overlapped.

In some embodiments, the stack structure 120 and the second trench 130 locate on the same side of the substrate 110. For example, in one embodiment, the stack structure 120 is on the upper surface 110a of the substrate 110, and the second trench 130 extends toward the bottom surface 110b of the substrate 110 and exposes the upper surface 110a of the substrate 110.

The first trench 131 exposes the fifth upper region 110c and the first upper region 110a-1 without coplanar with the fifth upper region 110c. The first step height H1 exists between the fifth upper region 110c and the first upper region 110a-1, and is substantially the same with the second depth D2 and/or the fifth depth D3. The first step height H1 can be 0.1 μm-10 μm, 2 μm-8 μm, or 3 μm-5 μm.

The second trench 130 is closer to the ridge structure 122R than the third trench 170 is. The third trench 170 can partially or fully connect to overlap with the second trench 130. The third trench 170 exposes the third upper region 110a-4, which is not coplanar with the second upper region 110a-2 and the sixth upper region 110a-3. The second step height d2 exists between the third upper region 110a-4 and the second upper region 110a-2, and the second step height d2 exists between the third upper region 110a-4 and the sixth upper region 110a-3. In other words, the third upper region 110a-4 is closer to the bottom surface 110b of the substrate 110 than the second upper region 110a-2 and the sixth upper region 110a-3 are. The second upper region 110a-2 can be coplanar with the sixth upper region 110a-3 and a continuous surface without forming a step height. In other embodiments, the second upper region 110a-2 is not coplanar with the sixth upper region 110a-3, and a step height exists between the second upper region 110a-2 and the sixth upper region 110a-3. The third upper region 110a-4 is closer to the bottom surface 110b of the substrate 110 than the fifth upper region 110c is. There is the third depth H2 between the top surface 122T and the third upper region 110a-4, and the third depth H2 is substantially the same with the first depth D1 between the first upper region 110a-1 and the top surface 122T. The third depth H2 can be 12 μm-35 μm, 18 μm-30 μm, or 20 μm-28 μm. The second step height d2 is substantially the same with the fourth depth dl and can be 8 μm-31 μm, 14 μm-26 μm, or 16 μm-24 μm. In the embodiment in the disclosure, since the fifth upper region 110c and the third upper region 110a-4 are formed by laser scribing, the roughness of the fifth upper region 110c and the third upper region 110a-4 are higher than that of the first upper region 110a-1, the second upper region 110a-2 and the sixth upper region 110a-3.

FIG. 6B shows a representative picture of the first trench 131′, the second trench 130′ and the third trench 170′ exposing the bottom surface 110b of the substrate 110 in accordance with one embodiment of the present disclosure. Some elements may be omitted in order to clarify the characters in the present disclosure.

The second trench 130′ and the ridge structure 122R respectively locate on the bottom surface 110b and the upper surface 110a. The second trench 130′ connects to the first trench 131′ and extends from the bottom surface 110b toward the upper surface 110a.

In some embodiments, the stack structure 120 and the second trench 130′ can respectively dispose on the opposite sides of the substrate 110. For example, the stack structure 120 locates on the upper surface 110a of the substrate 110. The second trench 130′ extends from the bottom surface 110b toward the upper surface 110a and exposes the first upper region 110a-1′, the second upper region 110a-2′ and the sixth upper region 110a-3′. In FIG. 6B, the second trench 130′ includes a first region 130-1, the second region 130-2 and the third region 130-3, and exposes different upper regions of the substrate 110. For example, the first upper region 110a-1′, the second upper region 110a-2′ and the sixth upper region 110a-3′ are exposed. The second trench 130′ includes different depths corresponding to different regions. For example, a sixth depth D1′ exists between the bottom electrode 150 and the first upper region 110a-1′, a seventh depth D2′ exists between the bottom electrode 150 and the second upper region 110a-2′, and an eighth depth D3′ exists between the bottom electrode 150 and the sixth upper region 110a-3′. In one embodiment, the sixth depth D1′, the seventh depth D2′ and the eighth depth D3′ are different. For example, the sixth depth D1′ is larger than the seventh depth D2′, and the seventh depth D2′ is the same with or different from the eighth depth D3′.

The first trench 131′ connects to, partially overlaps with, or fully overlaps with the second trench 130′. The first trench 131′ has a ninth depth dl′ and exposes the fifth upper region 110c′. The third trench 170′ connects to or overlaps with the second trench 130′ and includes a third step height d2′ to expose the third upper region 110a-4′. The ninth depth dl′ is substantially the same with the third step height d2′ and can be 8 μm-31 μm, 14 μm-26 μm, or 16 μm-24 μm.

The second trench 130′ is closer to the third side surface s3 of the substrate 110 than the first trench 131′ is. The first trench 131′ can connect with, partially overlap with or fully overlap with the second trench 130′. The first trench 131′ exposes the fifth upper region 110c′ and the first upper region 110a-1 without coplanar with the fifth upper region 110c′. In the embodiment, a fourth step height H1′ exists between the fifth upper region 110c′ and the first upper region 110a-1. The fourth step height H1′ is substantially the same with the seventh depth D2′ and the eighth depth D3′. The fourth step height H1′ can be 0.1 μm-10 μm, 2 μm-8 μm, or 3 μm-5 μm.

The third trench 170′ is closer to the third side surface s3 of the substrate 110 than the second trench 130′ is. The third trench 170′ can connect with, partially overlap with or fully overlap with the second trench 130′. The third trench 170′ exposes the third upper region 110a-4′, which is not coplanar with the second upper region 110a-2′ and/or the sixth upper region 110a-3′. A step height exists between the third upper region 110a-4′ and the second upper region 110a-2′, or between the third upper region 110a-4′ and the sixth upper region 110a-3′. The second upper region 110a-2′ can be coplanar with the sixth upper region 110a-3′ and a continuous surface is formed. In another embodiment, a step height exists between the second upper region 110a-2′ and the sixth upper region 110a-3′. The third upper region 110a-4′ is closer to the upper surface 110a of the substrate 110 than the fifth upper region 110c is. A tenth depth H2′ between the third upper region 110a-4′ and the bottom electrode 150 is substantially the same with the sixth depth D1′ between the first upper region 110a-1′ and the bottom electrode 150. The tenth depth H2′ can be 12 μm-35 μm, 18 μm-30 μm, or 20 μm-28 μm.

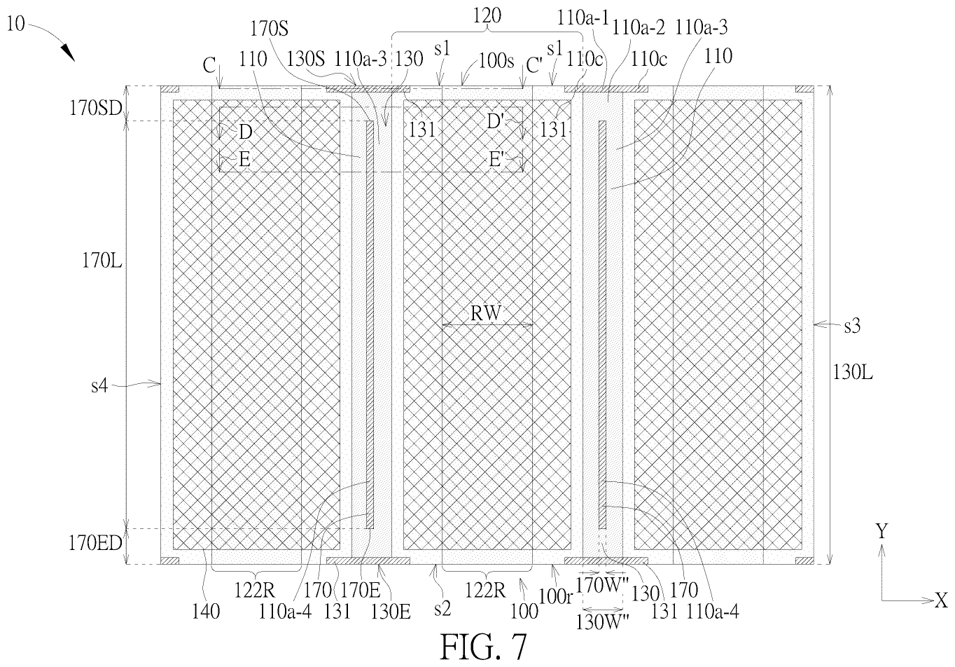

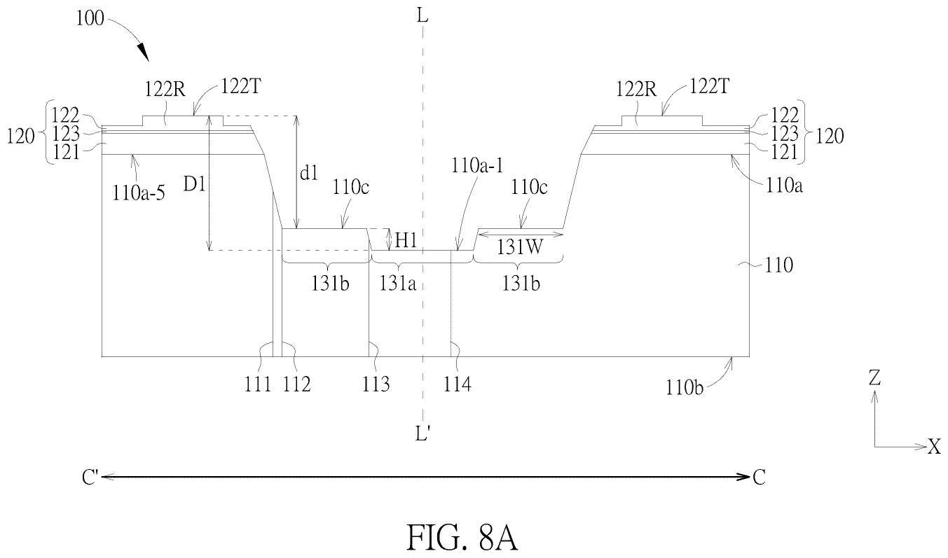

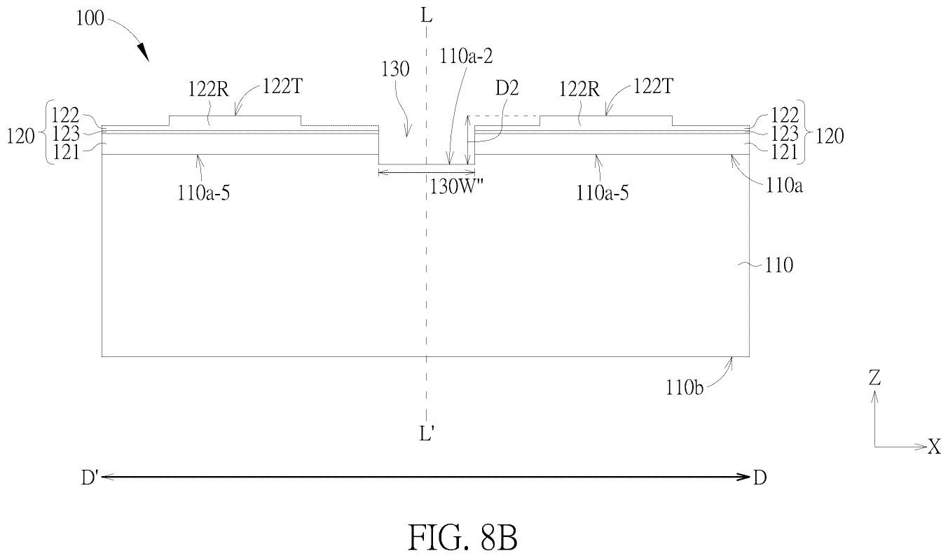

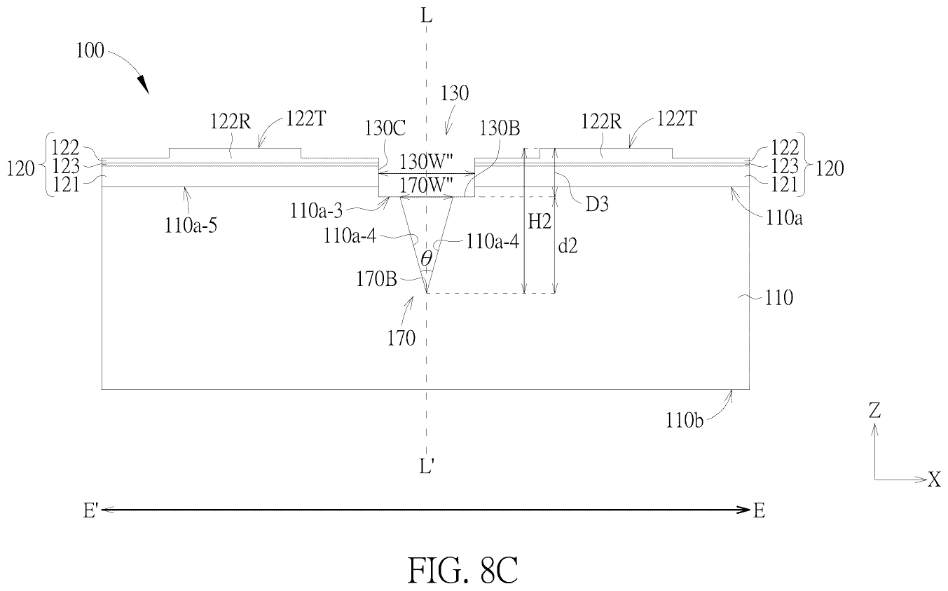

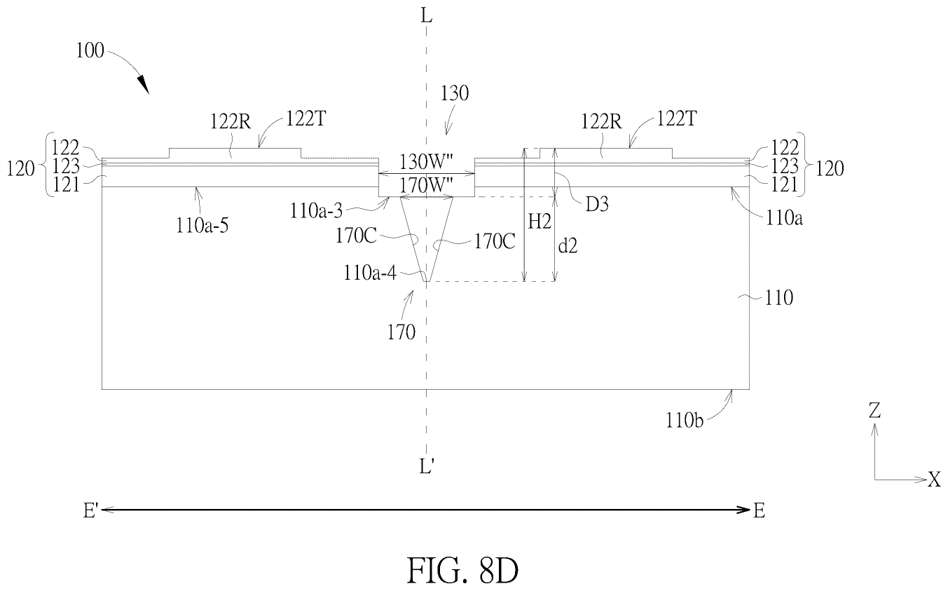

FIG. 7 shows a top view of semiconductor bar 10 in accordance with one embodiment of the present disclosure. The semiconductor bar 10 includes multiple unseparated semiconductor devices 100. FIG. 7 corresponds to a plane formed by X direction and Y direction. FIG. 8A shows a cross-sectional view along C-C′ line of the semiconductor bar 10 shown in FIG. 7. FIG. 8B shows a cross-sectional view along D-D′ line of the semiconductor bar 10 shown in FIG. 7. FIG. 8C shows a cross-sectional view along E-E′ line of the semiconductor bar 10 shown in FIG. 7. FIGS. 8A, 8B and 8C correspond to a plane formed by X direction and Z direction.

As shown in FIGS. 7, 8A, 8B and 8C, in order to divide the semiconductor bar 10 into individual multiple semiconductor devices 100, the second trenches 130 are formed on the substrate 110, and the third trenches 170 are formed in the second trenches 130. In one embodiment, the second trench 130 disposes on one side of the substrate 110 along the ridge structure 122R. In one embodiment, several second trenches dispose on the substrate 110 along the ridge structure 122R, and the ridge structure 122R is between two adjacent second trenches 130. In other words, the second trench 130 is between two adjacent ridge structures 122R. The first upper region 110a-1, the second upper region 110a-2 and the fifth upper region 110a-3 are substantially flat surfaces. As shown in FIGS. 8A-8D, the semiconductor bar 10 is divided to form multiple semiconductor devices 100 by applying an external stress. For example, the external stress can be applied by knife-cutting process, roller-cutting process or press-cutting process.

FIG. 8A shows a cross-sectional view of C-C′ line corresponding to the first trench 131 of the semiconductor bar 10. FIG. 8B shows a cross-sectional view of D-D′ line corresponding to the second trench 130 of the semiconductor bar 10. FIG. 8C shows a cross-sectional view of E-E′ line corresponding to the second trench 130 and the third trench 170, of the semiconductor bar 10. In addition, the second trench 130 of the semiconductor bar 10 includes a second pre-trench width 130W″ and a second trench length 130L. In FIG. 8A, the first trench 131 has the first depth D1 corresponding to a cross-sectional view of C-C′ line. In FIG. 8B, the second trench 130 has the second depth D2 corresponding to a cross-sectional view of D-D′ line. In FIG. 8C, the third trench 170 has the third depth H2 corresponding to a cross-sectional view of E-E′ line. The first depth D1, the second depth D2 and the third depth H2 are defined by the distances from the top surface 122T of the ridge structure 122R, which is farthest from the substrate 110, to the upper regions of the substrate 110. The first depth D1, the second depth D2 and the third depth H2 are parallel to Z direction.

In FIGS. 7, 8C, 8B, 8D, the third trench 170 has a third pre-trench width 170W″, the third trench length 170L and the third depth H2. In one embodiment, the third trench 170 disposes on one side of the substrate 110 along X-direction of the ridge structure 122R. In another embodiment, several third trenches 170 dispose on the substrate 110 along the ridge structure 122R, and the ridge structure 122R is between two adjacent third trenches 170. In other words, the third trench 170 is between two adjacent ridge structures 122R. The third trench 170 exposes the third upper region 110a-4. Especially, the third trench 170 is partially overlapped with the second trench 130. From the top view of the semiconductor device 100, the third trench 170 extends from the second trench 130 toward the inner side of the substrate 110, and a trench-in trench structure is formed.

In some embodiments as shown in FIG. 7, the third trench 170 has a flat bottom surface or a rough bottom surface, such as the third upper region 110a-4. In some embodiments, the third trench 170 includes the second step height d2 between the third upper region 110a-4 and the sixth upper region 110a-3. The second step height d2 can be the same with or different from the fourth depth dl. In some embodiments, the sum of the fifth depth D3 and the second step height d2 is substantially same with the first depth D1. In some embodiments as shown in FIG. 8A, the first trench 131 has the first depth D1, which is the sum of the fourth depth dl and the first step height H1, that is, D1=H1+d1.

In one embodiment, the third pre-trench width 170W″ is smaller than the second pre-trench width 130W″. In one embodiment, the third pre-trench width 170W″ can be 3 μm-17 μm, 6 μm-14 μm, or 8 μm-12 μm. The second pre-trench width 130W″ can be 5 μm-30 μm, 15 μm-25 μm, or 17 μm-23 μm.

In FIG. 7, the third trench 170 has a third trench starting point 170S near the reflective end face 100s and a third trench end point 170E near the light emitting end face 100r. The third trench starting point 170S does not directly contact the reflective end face 100s and spaces apart from the reflective end face 100s in a distance. In one embodiment, a starting distance 170SD is formed between the third trench starting point 170S and the reflective end face 100s. The starting distance 170SD is larger than 1 μm, 10 μm, 20 μm or 30 μm, and less than 50 μm. Similarly, the third trench end point 170E does not directly contact the light emitting end face 100r and spaces apart from the light emitting end face 100r in a distance. In one embodiment, an end distance 170ED is formed between the third trench end point 170E and the light emitting end face 100r. The end distance 170ED is larger than 1 μm, 10 μm, 20 μm or 30 μm, and less than 50 μm. In one embodiment, the starting distance 170SD can be the same as the end distance 170ED, or the starting distance 170SD can be larger or smaller than the end distance 170ED.

From a top view of the semiconductor device 100, the second trench 130 has a second trench starting point 130S near the reflective end face 100s and a second trench end point 130E near the light emitting end face 100r. The second trench starting point 130S and the first trench 131 can be formed together on the first side surface s1 of the substrate 110, and/or the second trench end point 130E and the first trench 131 can be formed together on the second side surface s2 of the substrate 110. In one embodiment, the second trench starting point 130S can be closer to the reflective end face 100s than the third trench starting point 170S. In another embodiment, the second trench end point 130E can be closer to the light emitting end face 100r than the third trench end point 170E.

In FIG. 8C, the third trench 170 has a wedge-like shape from a cross sectional view on X-Z plane. In some embodiments, from a cross-sectional view, such as X-Z plane, of the semiconductor device 100, the third upper region 110a-4 of the third trench 170 directly connects to the sixth upper region 110a-3. The third upper region 110a-4 is an inclined surface not perpendicular to the sixth upper region 110a-3 of the substrate 110. A base angle θ of the wedge can be larger than 10 degree, for example, 10-25 degree. The base angle θ is defined by an angle between two adjacent third upper regions 110a-4. The second step height d2 can be defined by a distance between the sixth upper region 110a-3 and a bottom point 170B of the third trench 170 as shown in FIG. 8C. The second step height d2 can be 8 μm-31 μm, 14 μm-26 μm, or 16 μm-24 μm.

In FIG. 8D, the third trench 170 has a trapezoid-like shape from a cross sectional view on X-Z plane. In some embodiments, from a cross-sectional view, such as X-Z plane, of the semiconductor device 100, the third trench 170 has the third upper region 110a-4 and an inclined surface 170C, and the third upper region 110a-4 connects to the sixth upper region 110a-3 via the inclined surface 170C. The third upper region 110a-4 can be the bottom surface of the third trench 170 and substantially parallel to the sixth upper region 110a-3. The second step height d2 can be defined by a distance between the sixth upper region 110a-3 and the third upper region 110a-4, and the second step height d2 is parallel to Z direction.

In FIG. 8A, the substrate 110 further includes one or more cracks, such as cracks 111, 112, 113 and 114. In one embodiment, the cracks 111, 112, 113 and 114 may locate on the reflective end face 110s or light emitting end face 100r (not shown here). The cracks 111, 112, 113 and 114 extend from the first trench 131 and/or second trench 130 toward the bottom surface 110b of the substrate 110. The extending direction of the cracks mentioned above can be substantially parallel to Z direction. In one embodiment, the first trench 131 has the first trench width 131W. The first trench width 131W can be 15 μm-35 μm, 20 μm-30 μm or 22 μm-28 μm. In one embodiment, the amount of the cracks extending from the first trench 131 is more than that extending from the second trench 130.

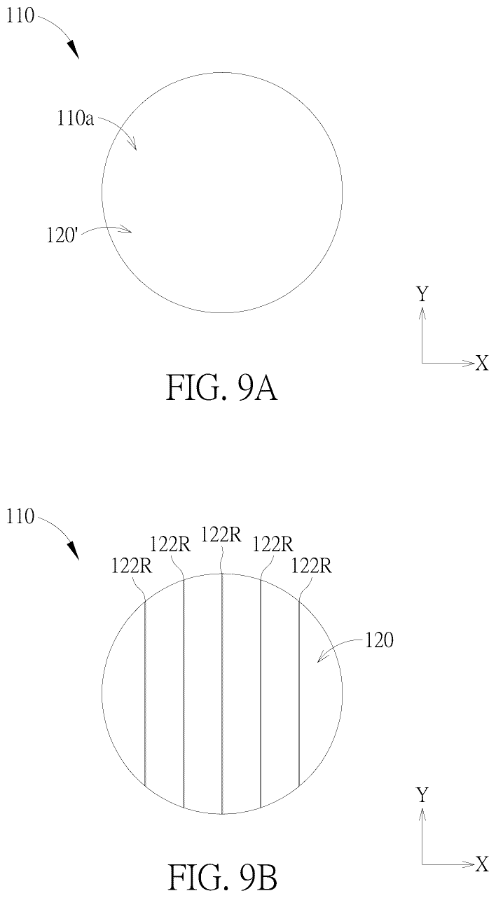

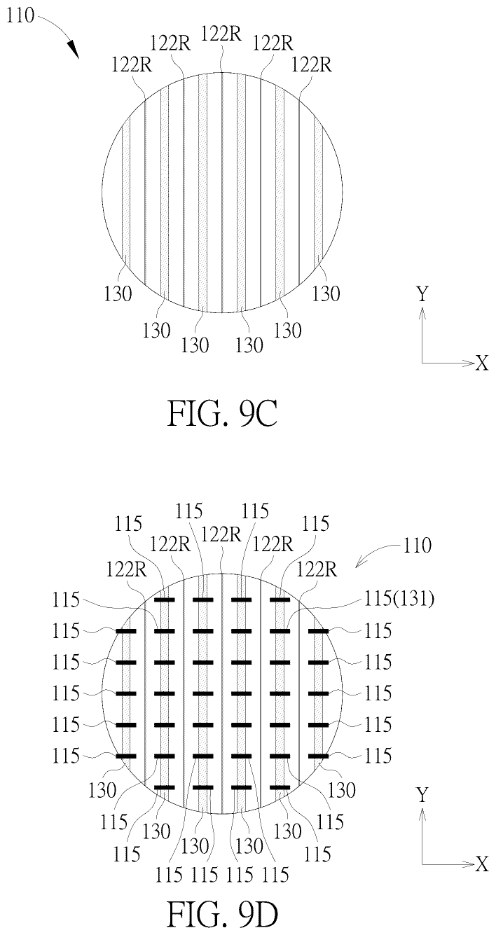

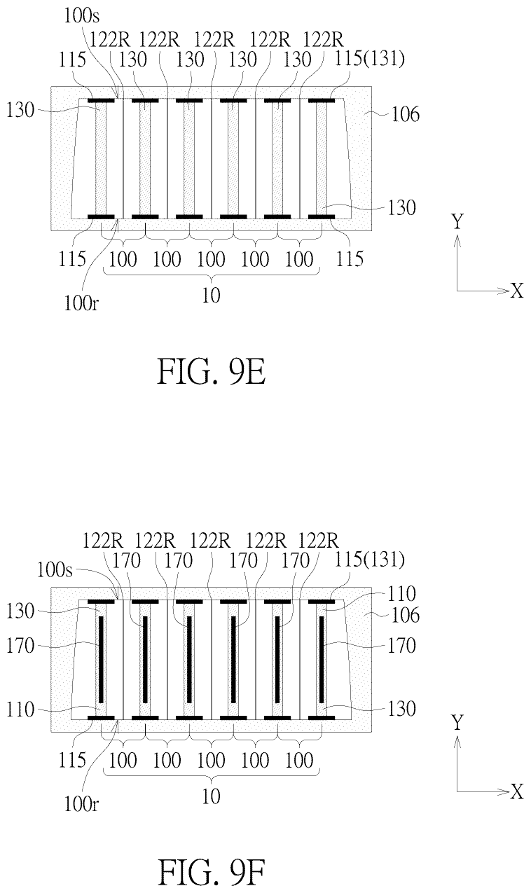

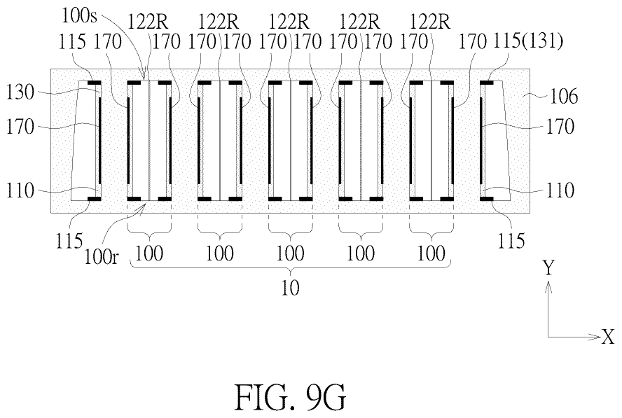

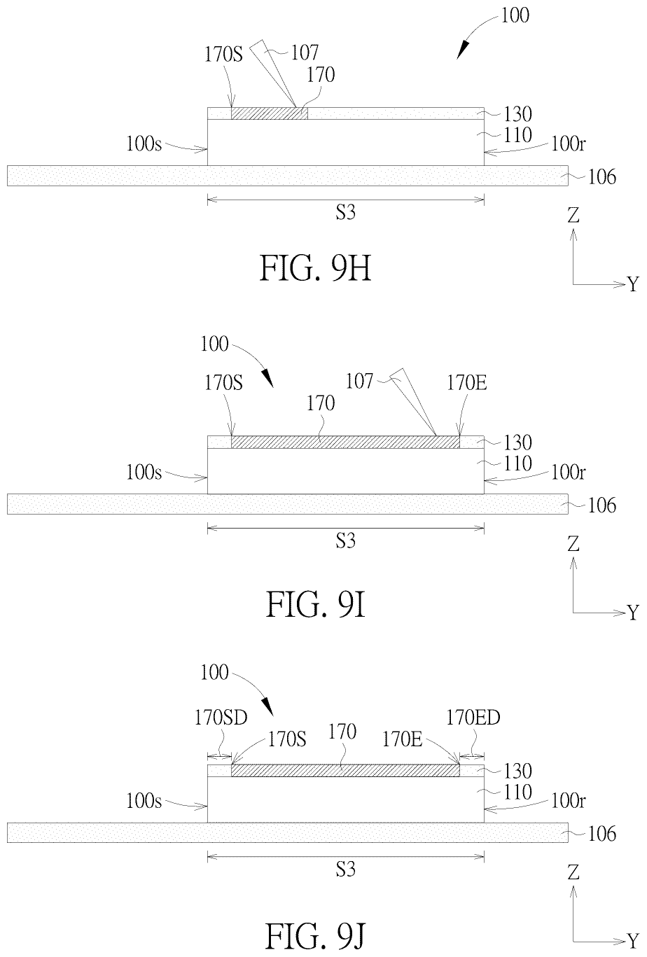

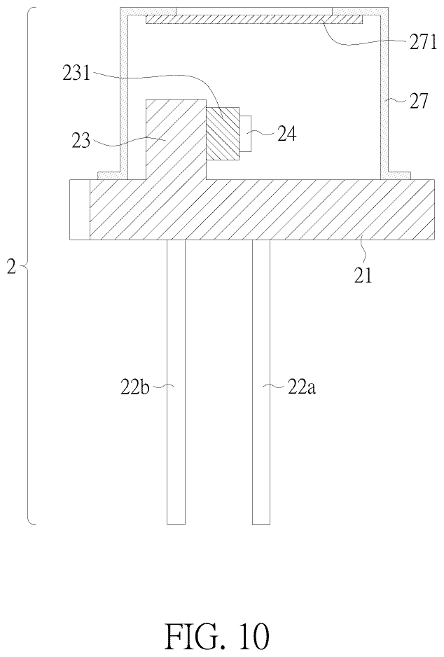

FIGS. 9A-9J show a process flow of manufacturing the semiconductor device 100 in accordance with other embodiments of the present disclosure. FIGS. 9A-9G correspond to a plane formed of X direction and Y direction. FIGS. 9H-9J correspond to a plane formed of Y direction and Z direction. Some elements may be omitted in FIGS. 9A-9J in order to clarify the characters in the present disclosure.

As shown in FIG. 9A, a substrate 110 is provided and a pre-stack structure 120′ is formed on the upper surface 110a of the substrate 110. The pre-stacking structure 120′ sequentially includes the first semiconductor layer (not shown), the active region (not shown), the second semiconductor layer (not shown) and the contact layer (not shown) on the upper surface 110a of the substrate 110 along Z direction. The pre-stack structure 120′ can be formed by but not limit to the following procedures: metal-organic vapor phase epitaxy (MOVPE), metal organic chemical vapor deposition (MOCVD), Hydride vapor phase epitaxy (HYPE), or molecular beam epitaxy (MBE).

In FIG. 9B, the ridge structure 122R as shown in FIGS. 1-4 and 7 is defined by removing a part of the second semiconductor layer (not shown) through Inductively-Coupled-Plasma (ICP) dry etching process. Therefore, the stack structure 120 as shown in FIGS. 2-5 sequentially including the first semiconductor layer 121, the active region 123 and the second semiconductor layer 122 along Z direction is formed. The ridge structure 122R includes a part of the second semiconductor layer 122 along the stacking direction.

Then, a part of the stack structure 120 is selectively removed through ICP dry etching process or wet etching process as shown in FIG. 9C. The second trenches 130 are formed on two sides of the ridge structure 122R formed by previous step and substantially parallel to the ridge structure 122R. After that, the other elements, such as the upper electrode 140, the bottom electrode 150 and the protective layer 160 as shown in FIG. 3 are formed.

In FIG. 9D, a part of the substrate (not shown) and a part of the stack structure (not shown) are removed by imposing a laser perpendicular to the extending direction of the ridge structure 122R. For example, the laser discontinuous scribes the two sides of the ridge structure 122R, and the scribing directions are perpendicular to the second trenches 130. Therefore, the scribe lines 115 as shown by dotted lines in FIG. 9D are formed. The multiple scribe lines 115 are separated from each other. After the process mentioned above, the first trench 131 as shown in FIGS. 1-2, 6A-6B, 7 and 8A is formed. To facilitate splitting in subsequent processes, the length of the scribe lines 115 can be but not limited to be 40 μm-100 μm, 50 μm-90 μm or 60 μm-80 μm.

In FIG. 9E, an external stress is applied on the scribe lines 115 by knife-cutting process, roller-cutting process or press-cutting process. Cracks appear along the scribe lines 115, and the substrate 110 and the stack structure (not shown) on the substrate 110 are divided to form multiple semiconductor bar 10. After that, the high reflective structure 100RS and the low reflective structure 100ES respectively form on the reflective end face 100s and the light emitting end face 100r as shown in FIG. 5, and the light resonator is produced. Then, the semiconductor bar 10 is transferred and temporarily fixed on a stage. For example, the semiconductor bar 10 is transferred and pasted on an adhesive film 106. The adhesive film can be polymer attach film having a melting point lower than that of the substrate 110. The shape of the adhesive film can deform but not break when sufficient external stress is applied. The semiconductor bar 10 includes multiple semiconductor devices 100 as shown in FIG. 9E.

In FIG. 9F, the third trenches 170 are formed by continuously or discontinuously imposing laser on two sides of the ridge structures 122R, and a part of the substrate 110 is removed. The laser is applied along the extending direction of the second trench 130. For facilitating the next splitting process, the third trench 170 can be designed to have the second step height d2 as shown in FIG. 4, and the second step height d2 can be but not limited to be 8 μm-31 μm, 14 μm-26 μm, or 16 μm-24 μm.

In FIG. 9G, after forming the third trench 170 away from the reflective end face 100s and the light emitting end face 100r by imposing laser, the adjacent semiconductor devices 100 are separated along the third trenches 170 of the semiconductor bar 10 by stretching the adhesive film 106 along X direction. After that, multiple semiconductors 100 as shown in FIG. 1 are produced after removing the adhesive film 106. As shown in FIG. 2, each of the semiconductor device 100 includes the substrate 110, the stack structure 120, the second trench 130 and the third trench 170.

FIGS. 9H-9J show a process of forming the third trench 170 according to FIG. 9F. FIGS. 9F-9J show that when forming the third trench 170 in the second trench 130 by applying laser, the third trench starting point 170S and the third trench end point 170E are respectively distant from the reflective end face 100s and the light emitting end face 100r of the semiconductor device 100. As shown in FIG. 91, the starting distance 170SD is formed between the third trench starting point 170S and the reflective end face 100s, and the end distance 170ED is formed between the third trench end point 170E and the light emitting end face 100r.

Comparing to the conventional semiconductor device which has a third trench starting point on the reflective end face and a third trench end point on the light emitting end face, the third trench starting point 170S and the third trench end point 170E in the semiconductor device 100 in the present disclosure are respectively devoid of contacting the reflective end face 100s and the light emitting end face 100r. Therefore, the pollution of the reflective end face 100s and the light emitting end face 100r caused by the splatters generated from the laser cutting process can be eliminated. More specifically, when the laser 107 cuts the substrate 110 and further cuts the adhesive film 106 downwardly, the adhesive film 106 for fixing the substrate 110 can produce some splatters polluting the reflective end face 100s and the light emitting end face 100r. In the present disclosure, since there are no splatters to pollute the reflective end face 100s and the light emitting end face 100r and to influence the light emitting of the resonator, the problem of yield loss by the pollution can be solved.

Since the third trench 170 is formed by applying laser 107, the profile of the third trench 170 would be V shape or trapezoid with non-specific crystal surface as shown in FIG. 8C, or would be “U” shape or trapezoid as shown in FIGS. 6A, 6B. the third trench width 170W and the third depth H2 are determined by the laser focusing energy and the laser efficiency.

FIG. 10 shows a cross-sectional view of the semiconductor system 2 in accordance with another embodiment of the present disclosure. As shown in FIG. 10, the semiconductor system 2 includes a heat sink 21, a first pin 22a, a second pin 22b, a fix seat 23, a secondary fix seat 231, a laser diode chip 24 and a metal cap 27. The first pin 22a and the second pin 22b locate on the rear side of the heat sink 21. The fix seat 23 protrudes to and locates on a surface of the heat sink 21, and the fix seat 23 connects to the second pin 22b which is grounding (GND). The secondary fix seat 231 is on the inner side of the fix seat 23 and connects to the laser diode chip 24. The metal cap 27 further includes a glass window 271 on top of the metal cap 27. The bottom side of the metal cap 27 connects to the heat sink 21. The laser diode chip 24 can include the semiconductor device mentioned in the above embodiments, such as the semiconductor device 100.

It should be appreciated that the scope of the present disclosure is not limited to the technical solution of specific combination of the abovementioned technical features shown in the drawings, but also covers other technical solutions of any combinations of the abovementioned technical features or the equivalents. The embodiments described above may be arbitrarily combined to form new embodiments, and all the new embodiments formed by the combinations are within the protection scope of the present disclosure.

Although some embodiments of the present disclosure and advantages thereof have been described, it should be appreciated that those skilled in the art can make changes, substitutions and modifications without departing from the spirit and scope of the present application. For example, those skilled in the art may readily understand that many of the components, functions, processes, and materials described herein may be changed without departing from the scope of the present disclosure. In addition, the protection scope of the present disclosure is not limited to the process, machine, manufacture, material composition, method and steps in the specific embodiments described herein. It should be readily appreciated by those skilled in the art that the current or future developed processes, machines, manufactures, material compositions, devices, methods and steps can be used in accordance with the present application as long as they can perform substantially the same functions or obtain substantially the same results in the embodiments described herein. Therefore, the protection scope of the present application includes the abovementioned process, machine, manufacture, material compositions, device, method and steps.

What is claimed is:

1. A semiconductor device, comprising:
a substrate comprising a first upper region, a second upper region a third upper region and a fourth upper region; and
a stack structure locating on the fourth upper region of the substrate without overlapping the first upper region, the second upper region and the third upper region, wherein the stack structure comprises a first end face, a top surface, a first semiconductor layer, an active region, and a second semiconductor layer comprising a ridge structure;
wherein the first upper region is closer to the first end face than the second upper region is, and the semiconductor device comprises a first depth between the top surface and the first upper region, and a second depth between the top surface and the second upper region smaller than the first depth.

2. The semiconductor device as claimed in claim 1, wherein the semiconductor device comprises a device width between 130 μm and 260 μm.

3. The semiconductor device as claimed in claim 1, wherein the semiconductor device comprises a device length between 840 μm and 1560 μm.

4. The semiconductor device as claimed in claim 1, wherein the semiconductor device comprises a device height between 70 μm and 120 μm.

5. The semiconductor device as claimed in claim 1, wherein the second upper region is closer to the first end face than the third upper region is, and the semiconductor device comprises a third depth between the top surface and the third upper region larger than the second depth.

6. The semiconductor device as claimed in claim 5, wherein the third depth is substantially the same as the first depth.

7. The semiconductor device as claimed in claim 1, wherein the substrate further comprises a fifth upper region closer to the first end face than the second upper region, and the semiconductor device comprises a fourth depth between the top surface and the fifth upper region larger than the second depth.

8. The semiconductor device as claimed in claim 5, wherein the substrate further comprises a sixth upper region closer to the ridge structure than the third upper region, and the semiconductor device comprises a fifth depth between the top surface and the sixth upper region, and the fifth depth is smaller than third depth.

9. The semiconductor device as claimed in claim 8, wherein the fifth depth is substantially the same as the second depth.

10. The semiconductor device as claimed in claim 1, wherein the substrate further comprises a first trench exposing the first upper region, and the first trench comprises a first trench width and a first trench length.

11. The semiconductor device as claimed in claim 10, wherein the substrate further comprises a second trench exposing the second upper region, and the second trench comprises a second trench width narrower than the first trench width, and a second trench length larger than the first trench length.

12. The semiconductor device as claimed in claim 11, wherein the substrate further comprises a third trench parallel to the second trench, and the third trench comprises a third trench width narrower than the second trench width, and a third trench length smaller than the second trench length.

13. The semiconductor device as claimed in claim 10, wherein the substrate comprises an outer short-side surface, an outer long-side surface and a corner between the outer short-side surface and the outer long-side surface,
wherein the first trench locates at the corner.

14. The semiconductor device as claimed in claim 12, wherein the second trench is closer to the ridge structure than the third trench is.

15. The semiconductor device as claimed in claim 11, wherein the first trench connects to the second trench.

16. The semiconductor device as claimed in claim 12, wherein the second trench connects to the third trench, and the first trench separates from the third trench.

17. The semiconductor device as claimed in claim 11, wherein the second trench length is between 840 μm and 1560 μm and the second trench width is between 5 μm and 15 μm.

18. The semiconductor device as claimed in claim 12, wherein the third trench width is between 3 μm and 7 μm.

19. The semiconductor device as claimed in claim 1, wherein the ridge structure comprises a ridge width between 35 μm and 65 μm.

20. The semiconductor device as claimed in claim 10, wherein the first trench comprises a first part, a second part and a first step height between the first part and the second part, and wherein the first step height is substantially the same as the second depth.
